(19) United States
(12) Patent Application Publication
(10) Pub. No.: US 2026/0206579 A1
(43) Pub. Date: Jul. 16, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Pao-Hung TSENG, Taichung City (TW); Yu-Cheng PAI, Taichung City (TW); Yuan-Ping YEH, Taichung City (TW)

(73) Assignee: SILICONWARE PRECISION INDUSTRIES CO., LTD., Taichung City (TW)

(21) Appl. No.: 19/240,598

(22) Filed: Jun. 17, 2025

(30) Foreign Application Priority Data
Jan. 10, 2025 (TW) 114101164

(51) Int. Cl. H01L 23/36; H01L 23/00; H01L 23/31

(52) U.S. Cl. CPC H10W 40/10; H10W 74/111; H10W 70/09; H10W 70/60

(57) ABSTRACT

Provided are an electronic package and a manufacturing method thereof. The electronic package is made by disposing an electronic component on a heat dissipation layer, encapsulating the electronic component with an encapsulation layer, forming a circuit structure on the encapsulation layer, and forming a thermal conductive pillar in the encapsulation layer. Accordingly, the heat dissipation layer is connected to the electronic component and the thermal conductive pillar in a thermally conductive manner, and therefore, the heat of the electronic component can be transferred to the heat dissipation layer to improve the heat dissipation performance of the electronic package.

### BACKGROUND

### 1. Technical Field

The present disclosure relates to a semiconductor package, and more particularly, to an electronic package with a heat dissipation layer and a manufacturing method of the electronic package.

### 2. Description of Related Art

As a demand for electronic products in terms of functions and processing speed increases, semiconductor chips, as the core components of electronic products, require electronic components and electronic circuits with higher densities, and thus more heat will be generated by the semiconductor chips during their operation.

However, the conventional encapsulant encapsulating the semiconductor chip is a poor thermal conductive material with a thermal conductivity of only 0.8 W·m−1·k−1 (i.e., poor heat dissipation efficiency), and thus the heat generated by the semiconductor chip cannot be effectively dissipated often, causing damage to the semiconductor chip and reliability issues of electronic products.

Therefore, how to overcome the above-mentioned problems of conventional techniques has become an urgent issue to be solved.

### SUMMARY

In view of the above-mentioned shortcomings of the prior art, the present disclosure provides an electronic package including: a heat dissipation layer; a first electronic component disposed on the heat dissipation layer in a thermally conductive manner and having at least one first thermal conductive pad; an encapsulation layer formed on the heat dissipation layer to encapsulate the first electronic component; a circuit structure formed on the encapsulation layer and including at least one insulation layer and a circuit layer coupled to the insulation layer, such that the circuit layer is electrically connected to the first electronic component; and a first thermal conductive pillar disposed within the encapsulation layer, connected to the heat dissipation layer in a thermally conductive manner, and coupled to the first thermal conductive pad through the circuit layer in a thermally conductive manner.

The present disclosure also provides a manufacturing method of an electronic package, comprising: disposing at least one first electronic component having at least one first thermal conductive pad on a heat dissipation layer in a thermally conductive manner; forming an encapsulation layer on the heat dissipation layer to encapsulate the first electronic component; and forming a circuit structure on the encapsulation layer, and forming a first thermal conductive pillar within the encapsulation layer, such that the first thermal conductive pillar is coupled to the heat dissipation layer in a thermally conductive manner, wherein the circuit structure includes at least one insulation layer and a circuit layer coupled to the insulation layer, the circuit layer is electrically connected to the first electronic component, and the first thermal conductive pillar is coupled to the first thermal conductive pad through the circuit layer in a thermally conductive manner.

The aforementioned manufacturing method further include: disposing at least one second electronic component having at least one second thermal conductive pad on the heat dissipation layer in a thermally conductive manner, and electrically connecting the second electronic component to the circuit layer; and forming a second thermal conductive pillar within the encapsulation layer, in a manner that the second thermal conductive pillar is coupled to the heat dissipation layer in a thermally conductive manner, and coupled to the second thermal conductive pad through the circuit layer in a thermally conductive manner.

For instance, a width of the first thermal conductive pad is larger than or equal to a width of the second thermal conductive pad, or a width of the first thermal conductive pillar is larger than or equal to a width of the second thermal conductive pillar. A heat generated by the first electronic component is even more than the heat generated by the second electronic component.

Furthermore, a thickness of the heat dissipation layer in an area corresponding to the first electronic component is greater than a thickness of the heat dissipation layer in an area corresponding to the second electronic component.

In addition, the encapsulation layer may further encapsulate the second electronic component and the second thermal conductive pillar.

The aforementioned electronic package and the manufacturing method, the heat dissipation layer in an area corresponding to the first thermal conductive pillar has a greater thickness.

It can be seen from above, the electronic package and the manufacturing method thereof of the present disclosure mainly form a first thermal conductive pad on the first electronic component disposed within the heat dissipation layer, and the first thermal conductive pad is connected to the first thermal conductive pillar in a thermally conductive manner. Therefore, the heat of the first electronic component can be transferred to the heat dissipation layer to improve the heat dissipation performance of the electronic package. Compared to the conventional techniques, the electronic package of the present disclosure can disperse the thermal stress to prevent the first electronic component from cracking, thereby improving the reliability of electronic products.

### BRIEF DESCRIPTION OF THE DRAWINGS

FIG. 1A to FIG. 1D are schematic cross-sectional views for the manufacturing method of an electronic package of the present disclosure.

FIG. 2 is a schematic cross-sectional view of another embodiment of the electronic package of the present disclosure.

FIG. 3 is a schematic cross-sectional view of the other embodiment of the electronic package of the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

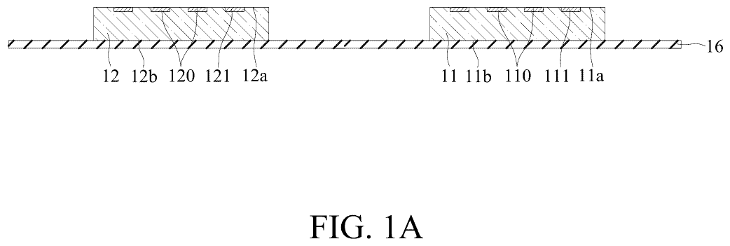

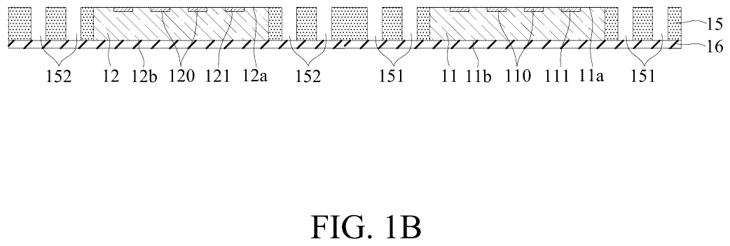

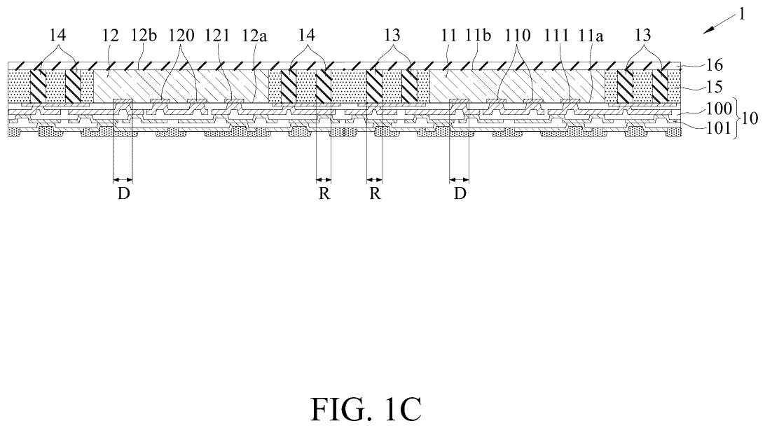

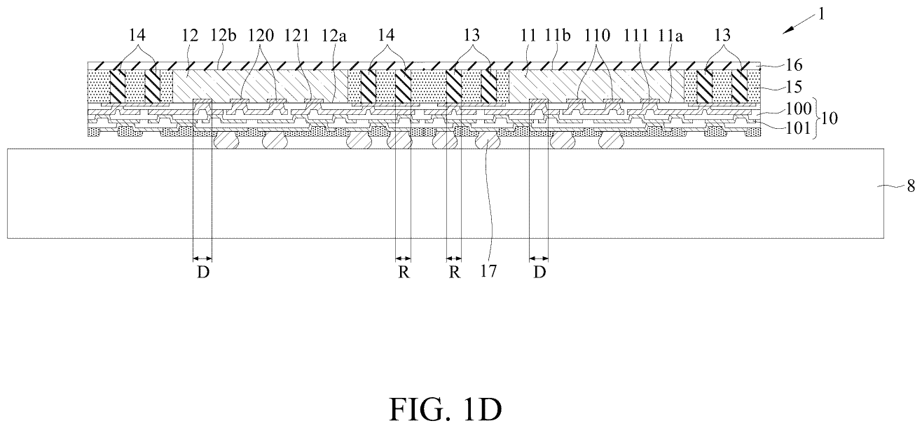

FIG. 1A to FIG. 1D are schematic cross-sectional views for the manufacturing method of an electronic package 1 of the present disclosure.

As shown in FIG. 1A, disposing at least one first electronic component 11 and at least one second electronic component 12 on a heat dissipation layer 16 of a carrier (not shown), and the heat dissipation layer 16 is connected to the first electronic component 11 and the second electronic component 12 in a thermally conductive manner.

The first electronic component 11 disposed on the heat dissipation layer 16 is an active component, a passive component or a combination thereof. The active component is for example a semiconductor chip, and the passive component is for example a resistor, a capacitor or an inductor.

In this embodiment, the first electronic component 11 is a semiconductor chip having a first active surface 11a and a first inactive surface 11b opposite to the first active surface 11a, and the first active surface 11a has a plurality of first electrode pads 110 and at least one first thermal conductive pad 111. The first inactive surface 11b faces the heat dissipation layer 16 and is disposed on and connected to the heat dissipation layer 16, such that the heat dissipation layer 16 tis connected to the first electronic component 11 in a thermally conductive manner. For instance, the first thermal conductive pad 111 is located near a hotspot of the first electronic component 11.

The second electronic component 12 is an active component, a passive component or a combination thereof and is disposed on the heat dissipation layer 16. For example, the active component is a semiconductor chip, and the passive component is a resistor, a capacitor or an inductor.

In this embodiment, the second electronic component 12 is a semiconductor chip having a second active surface 12a and a second inactive surface 12b opposite to the second active surface 12a. The second active surface 12a has a plurality of second electrode pads 120 and at least one second thermal conductive pad 121, and the second inactive surface 12b faces the heat dissipation layer 16 and is disposed on and connected to the heat dissipation layer 16, such that the heat dissipation layer 16 is connected to the second electronic component 12 in a thermally conductive manner. For instance, the second thermal conductive pad 121 is located near a hotspot of the second electronic component 12.

The heat dissipation layer 16 is connected to the first electronic component 11 and the second electronic component 12 in a thermally conductive manner.

In this embodiment, the heat dissipation layer 16 is a metal layer such as a copper layer which contacts the first electronic component 11 and the second electronic component 12.

As shown in FIG. 1B, forming an encapsulation layer 15 on the heat dissipation layer 16 to encapsulate the first electronic component 11 and the second electronic component 12. Next, forming a plurality of first vias 151 and a plurality of second vias 152 within the encapsulation layer 15, and partial surfaces of the heat dissipation layer 16 are exposed from the plurality of first vias 151 and the plurality of second vias 152.

In this embodiment, the encapsulation layer 15 is an insulation material such as polyimide (PI), a dry film, or an encapsulant or a molding compound such as epoxy.

Furthermore, an upper surface of the encapsulation layer 15 is flush with the first active surface 11a and the second active surface 12a, such that the first electronic component 11 and the second electronic component 12 are exposed from the encapsulation layer 15.

In addition, the plurality of first vias 151 are located around the first electronic component 11, and the plurality of second vias 152 are located around of the second electronic component 12.

As shown in FIG. 1C, forming a circuit structure 10 on the encapsulation layer 15, such that the circuit structure 10 is electrically connected to the first electronic component 11 and the second electronic component 12. Forming a first thermal conductive pillar 13 in the first via 151, and forming a second thermal conductive pillar 14 in the second via 152, such that one end of the first thermal conductive pillar 13 and one end of the second thermal conductive pillar 14 are connected to the heat dissipation layer 16 in a thermally conductive manner.

In this embodiment, the circuit structure 10 includes an insulation layer 100 and a circuit layer 101 coupled to the insulation layer 100. For example, the circuit structure 10 is formed by a process of making a redistribution layer (RDL), a material used to form the circuit layer 101 is copper, and a material used to form the insulation layer 100 is a dielectric material such as Polybenzoxazole (PBO), Polyimide (PI) or Prepreg (PP), or a solder resistant material such as green paint or ink.

Furthermore, the circuit layer 101 is electrically connected to the plurality of first electrode pads 110 and the plurality of second electrode pads 120, and the circuit layer 101 is connected to the first thermal conductive pad 111, the first thermal conductive pillar 13, the second thermal conductive pad 121 and the second thermal conductive pillar 14 in a thermally conductive manner, such that the other end of the first thermal conductive pillar 13 and the other end of the second thermal conductive pillar 14 are connected to the first thermal conductive pad 111 and the second thermal conductive pad 121 through the circuit layer 101, respectively.

Furthermore, a plurality of the first thermal conductive pillars 13 surround the first electronic component 11, and a plurality of the second thermal conductive pillars 14 surround the second electronic component 12. For example, a material used to form the first thermal conductive pillar 13 and the second thermal conductive pillar 14 is a metal material such as copper or a solder material.

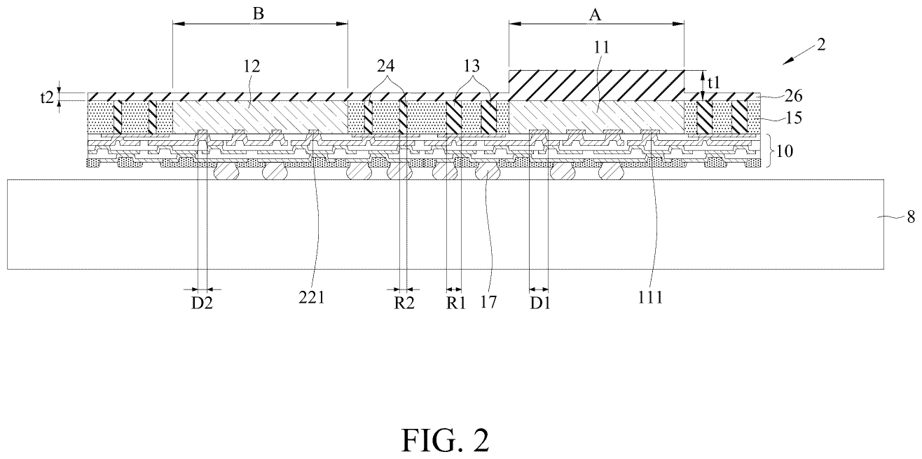

Furthermore, as shown in FIG. 1C, widths D of the first thermal conductive pad 111 and the second thermal conductive pad 121 are equal. Or as shown in FIG. 2, a width D1 of the first thermal conductive pad 111 can be selectively larger than a width D2 of the second thermal conductive pad 221.

In addition, as shown in FIG. 1C, widths R of the first thermal conductive pillar 13 and the second thermal conductive pillar 14 are equal. Alternatively, as shown in FIG. 2, a width R1 of the first thermal conductive pillar 13 is larger than a width R2 of the second thermal conductive pillar 24.

Therefore, the electronic package 1 of the present disclosure mainly disposes the first thermal conductive pad 111 and the second thermal conductive pad 121 on the first electronic component 11 and the second electronic component 12, respectively. The first thermal conductive pad 111 and the second thermal conductive pad 121 are connected to the first thermal conductive pillar 13 and the second thermal conductive pillar 14 through the circuit layer 101, respectively. As such, heat from the first electronic component 11 and the second electronic component 12 can be transferred to the heat dissipation layer 16 through the first thermal conductive pillar 13 and the second thermal conductive pillar 14 as well as the first inactive surface 11b and the second inactive surface 12b. The heat dissipation performance of the electronic package 1 can be significantly improved by using two heat transfer paths. Thus, compared to the conventional techniques, the electronic package 1 of the present disclosure can disperse the thermal stress to prevent the first electronic component 11 and the second electronic component 12 from cracking, thereby improving the reliability of electronic products.

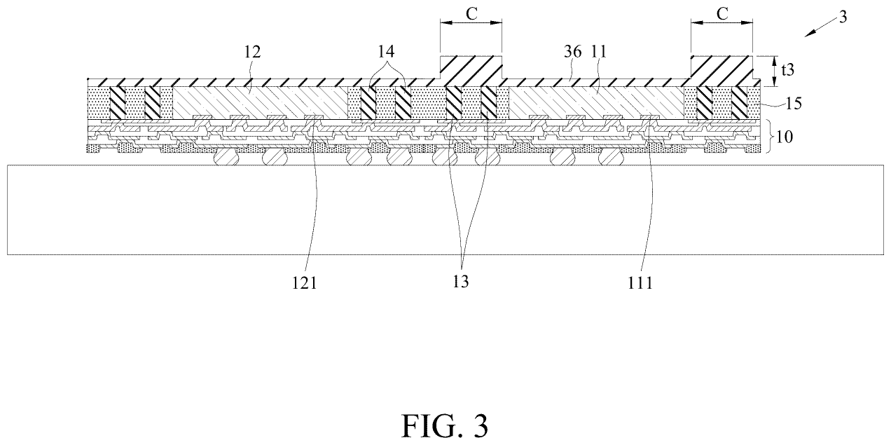

Further, thicknesses of the heat dissipation layer 16 in different areas can be designed according to the different requirements of heat dissipation. In an electronic package 2 shown in FIG. 2, when the first electronic component 11 generates more heat than the second electronic component 12 does, a thickness t1 of the heat dissipation layer 26 in an area A corresponding to the first electronic component 11 is greater than a thickness t2 of the heat dissipation layer 26 in an area B corresponding to the second electronic component 12. Or in an electronic package 3 as shown in FIG. 3, the heat dissipation layer 36 in an area C corresponding to the first thermal conductive pillar 13 has a greater thickness t3.

In addition, as shown in FIG. 1D, a plurality of conductive components 17 such as solder materials can be formed on the circuit structure 10 in subsequent processes for the electronic package 1 to be disposed on and connected to an external device such as a circuit board 8.

The present disclosure also provides the electronic package 1, 2, 3 including the heat dissipation layer 16, 26, 36, the first electronic component 11, the encapsulation layer 15, the circuit structure 10, and the first thermal conductive pillar 13.

The first electronic component 11 is disposed on the heat dissipation layer 16, 26, 36, the heat dissipation layer 16, 26, 36 is connected to the first electronic component 11 in a thermally conductive manner, and the first electronic component 11 has the at least one first thermal conductive pad 111.

The encapsulation layer 15 is formed on the heat dissipation layer 16, 26, 36 to encapsulate the first electronic component 11.

The circuit structure 10 is disposed on the encapsulation layer 15 and includes the at least one insulation layer 100 and the circuit layer 101 coupled to the insulation layer 100, such that the circuit layer 101 is electrically connected to the first electronic component 11.

The first thermal conductive pillar 13 is disposed within the encapsulation layer 15, the first thermal conductive pillar 13 is coupled to the heat dissipation layer 16, 26, 36 in a thermally conductive manner, and is coupled to the first thermal conductive pad 111 through the circuit layer 101 in a thermally conductive manner.

In an embodiment, the electronic package 1, 2, 3 further includes the second electronic component 12 disposed on the heat dissipation layer 16, 26, 36, the heat dissipation layer 16, 26, 36 is connected to the second electronic component 12 in a thermally conductive manner, and the second electronic component 12 having at least one second thermal conductive pad 121, 221 is electrically connected to the circuit layer 101; and the second thermal conductive pillar 14, 24 disposed within the encapsulation layer 15, such that the second thermal conductive pillar 14, 24 is connected to the heat dissipation layer 16, 26, 36 in a thermally conductive manner, and is coupled to the second thermal conductive pad 121, 221 through the circuit layer 101 in a thermally conductive manner.

For instance, the width D1 of the first thermal conductive pad 111 is larger than the width D2 of the second thermal conductive pad 221. Or the widths D of the first thermal conductive pad 111 and the second thermal conductive pad 121 are equal.

For instance, the width R1 of the first thermal conductive pillar 13 is larger than the width R2 of the second thermal conductive pillar 24. Or the widths R of the first thermal conductive pillar 13 and the second thermal conductive pillar 14 are equal.

The first electronic component 11 generates even more heat than the second electronic component 12 does.

Further, the thickness t1 of the heat dissipation layer 26 in the area A corresponding to the first electronic component 11 is greater than the thickness t2 of the heat dissipation layer 26 in the area B corresponding to the second electronic component 12.

In addition, the encapsulation layer 15 further encapsulates the second electronic component 12 and the plurality of second thermal conductive pillars 14, 24.

In an embodiment, the heat dissipation layer 36 in the area C corresponding to the first thermal conductive pillar 13 has the greater thickness t3.

In summary, the electronic package of the present disclosure forms the first thermal conductive pad 111 and the second thermal conductive pad 121 on the first electronic component 11 and the second electronic component 12 disposed on the heat dissipation layer, and the first thermal conductive pad and the second thermal conductive pad are connected to the first thermal conductive pillar and the second thermal conductive pillar in a thermally conductive manner, respectively. Therefore, the heat of the first electronic component and the second electronic component can be transferred to the heat dissipation layer to improve the heat dissipation performance of the electronic package. Accordingly, the electronic package of the present disclosure can disperse the thermal stress to prevent the first electronic component and the second electronic component from cracking, thereby improving the reliability of electronic products.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, including:
a heat dissipation layer;
a first electronic component disposed on the heat dissipation layer in a thermally conductive manner, wherein the first electronic component has a first thermal conductive pad;
an encapsulation layer formed on the heat dissipation layer to encapsulate the first electronic component;
a circuit structure disposed on the encapsulation layer and including an insulation layer and a circuit layer coupled to the insulation layer, such that the circuit layer is electrically connected to the first electronic component; and
a first thermal conductive pillar disposed within the encapsulation layer, connected to the heat dissipation layer in a thermally conductive manner, and coupled to the first thermal conductive pad through the circuit layer in a thermally conductive manner.

2. The electronic package of claim 1, further comprising:
a second electronic component disposed on the heat dissipation layer in a thermally conductive manner, and electrically connected to the circuit layer, wherein the second electronic component has a second thermal conductive pad; and
a second thermal conductive pillar disposed within the encapsulation layer, connected to the heat dissipation layer in a thermally conductive manner, and coupled to the second thermal conductive pad through the circuit layer in a thermally conductive manner.

3. The electronic package of claim 2, wherein a width of the first thermal conductive pad is larger than or equal to a width of the second thermal conductive pad.

4. The electronic package of claim 2, wherein a width of the first thermal conductive pillar is larger than or equal to a width of the second thermal conductive pillar.

5. The electronic package of claim 2, wherein a heat generated by the first electronic component is more than a heat generated by the second electronic component.

6. The electronic package of claim 2, wherein a thickness of the heat dissipation layer in an area corresponding to the first electronic component is greater than a thickness of the heat dissipation layer in an area corresponding to the second electronic component.

7. The electronic package of claim 2, wherein the encapsulation layer further encapsulates the second electronic component and the second thermal conductive pillar.

8. The electronic package of claim 1, wherein the heat dissipation layer in an area corresponding to the first thermal conductive pillar has a greater thickness.

9. The electronic package of claim 2, wherein the heat dissipation layer in an area corresponding to the first thermal conductive pillar has a greater thickness.

10. A manufacturing method of an electronic package, comprising:
disposing a first electronic component on a heat dissipation layer in a thermally conductive manner, wherein the first electronic component has a first thermal conductive pad;
forming an encapsulation layer on the heat dissipation layer to encapsulate the first electronic component; and
forming a circuit structure on the encapsulation layer, and forming a first thermal conductive pillar coupled to the heat dissipation layer in a thermally conductive manner within the encapsulation layer, wherein the circuit structure includes an insulation layer and a circuit layer coupled to the insulation layer, the circuit layer is electrically connected to the first electronic component, and the first thermal conductive pillar is coupled to the first thermal conductive pad through the circuit layer in a thermally conductive manner.

11. The manufacturing method of claim 10, further including:
disposing a second electronic component on the heat dissipation layer in a thermally conductive manner, and electrically connecting the second electronic component to the circuit layer, wherein the second electronic component has a second thermal conductive pad; and
forming a second thermal conductive pillar within the encapsulation layer, in a manner that the second thermal conductive pillar is connected to the heat dissipation layer in a thermally conductive manner, and coupled to the second thermal conductive pad through the circuit layer in a thermally conductive manner.

12. The manufacturing method of claim 11, wherein a width of the first thermal conductive pad is larger than or equal to a width of the second thermal conductive pad.

13. The manufacturing method of claim 11, wherein a width of the first thermal conductive pillar is larger than or equal to a width of the second thermal conductive pillar.

14. The manufacturing method of claim 11, wherein a heat generated by the first electronic component is more than a heat generated by the second electronic component.

15. The manufacturing method of claim 11, wherein a thickness of the heat dissipation layer in an area corresponding to the first electronic component is greater than a thickness of the heat dissipation layer in an area corresponding to the second electronic component.

16. The manufacturing method of claim 11, wherein the encapsulation layer further encapsulates the second electronic component and the second thermal conductive pillar.

17. The manufacturing method of claim 10, wherein the heat dissipation layer in an area corresponding to the first thermal conductive pillar has a greater thickness.

18. The manufacturing method of claim 11, wherein the heat dissipation layer in an area corresponding to the first thermal conductive pillar has a greater thickness.
